(19) United States
(12) Patent Application Publication
(10) Pub. No.: US 2025/0140657 A1
(43) Pub. Date: May 1, 2025

(54) SEMICONDUCTOR DEVICE AND METHOD OF FABRICATING SAME

(71) Applicant: IDEAL SEMICONDUCTOR DEVICES, INC., Bethlehem, PA (US)

(72) Inventor: Ryan Thorpe, Allen, TX (US)

(21) Appl. No.: 18/496,277

(22) Filed: Oct. 27, 2023

(51) Int. Cl. H01L 23/495; H01L 21/48; H01L 21/56; H01L 23/31

(52) U.S. Cl. CPC H01L 23/49575; H01L 21/4825; H01L 21/565; H01L 23/3107; H01L 23/4951; H01L 23/4952; H01L 23/49524; H01L 23/49562

(57) ABSTRACT

A semiconductor device includes first and second semiconductor die. The first die has a first surface and a second surface opposite the first surface, and includes a first active device including a first terminal on the first surface and a second terminal on the second surface. The second die has a third surface and a fourth surface opposite the third surface, and includes a second active device including a third terminal on the third surface and a fourth terminal on the fourth surface. The device includes a first interconnect layer between the first surface and the fourth surface, the first interconnect layer providing vertical separation between the first and second dies and providing electrical connection between the first terminal and the fourth terminal. The device includes a conductive element having a first end electrically connected to the third surface, and a second end electrically connected to a second leadframe. The second surface is electrically connected to a first leadframe.

### BACKGROUND

The present invention relates generally to semiconductor devices and fabrication, and, more particularly, to methods of fabricating a semiconductor device including multiple semiconductor chips.

Power switching applications, such as, for example, voltage regulators, power converters (e.g., direct current (DC)-DC converters, alternating current (AC)-DC converters, etc.), and the like, often employ a pair of serially-connected high-side and low-side vertical power transistors (e.g., metal-oxide-semiconductor field-effect transistors (MOSFETs) or insulated gate bipolar transistors (IGBTs)) integrated together in a semiconductor package.

A limiting factor in the efficiency of a voltage regulator is the time it takes for the drain current to rise and fall within the power MOSFETs used inside the regulator. For a high current voltage regulator, losses due to current rise and fall times may be larger than the losses due to gate-drain charge, Q_{GD}, associated with the device, which can affect voltage rise and fall times. The rise and fall times of the current are primarily limited by source inductance of the high-side transistor and total loop inductance (i.e., the inductance path from an input inductor, through the high-side and low-side transistors, and back to the input inductor).

Integrating the high-side and low-side power transistors into a single package can improve system efficiencies by reducing both package and loop inductance. When using MOSFET devices, the high-side and low-side MOSFETs are typically provided on different dies within a single semiconductor package such as a multi-chip module (MCM), with the high-side MOSFET having its drain connected to the voltage input and the low-side MOSFET having its source connected to ground. Alternatively, the two MOSFETs may be combined with a driver circuit. Typically, the high-side and low-side power transistors are placed on a ceramic substrate in a package leadframe, which is costly to manufacture.

Similarly, two diodes (e.g., Schottky diodes) may be connected together in series and integrated into a single packaged device. By connecting the diodes in series, a doubling of the voltage capability can be achieved, compared to a single diode, which may be beneficial for high-power applications. In conventional approaches for connecting two diodes in series, an insulating interposer layer (such as ceramic) is typically employed. The diodes are physically arranged side by side and a wire connection (e.g., a bond wire) is used for electrical interconnection. The insulating interposer layer may add significant cost and complexity to the semiconductor device, among other disadvantages, and is therefore undesirable.

### SUMMARY

The present invention, as manifested in one or more embodiments, beneficially provides enhanced methods for fabricating a semiconductor device comprising multiple vertical devices connected together in a series configuration.

In accordance with an embodiment, a semiconductor device is provided that includes first and second semiconductor die. The first semiconductor die comprises a first surface and a second surface opposite the first surface, and includes a first active device including a first terminal on the first surface and a second terminal on the second surface. The second surface is electrically connected to a first leadframe of the semiconductor device. The second semiconductor die comprises a third surface and a fourth surface opposite the third surface, and includes a second active device including a third terminal on the third surface and a fourth terminal on the fourth surface. The semiconductor device further includes a first interconnect layer between the first surface and the fourth surface, the first interconnect layer providing vertical separation between the first and second semiconductor dies and providing electrical connection between the first terminal and the fourth terminal. The semiconductor device includes a conductive element having a first end electrically connected to the third surface, and a second end electrically connected to a second leadframe of the semiconductor device.

In accordance with another embodiment, a semiconductor device is provided that includes a first semiconductor die including a first active device formed therein, the first semiconductor die comprising a first upper surface and a first bottom surface opposite the first upper surface, the first semiconductor die electrically connected to a first leadframe and configured such that the first bottom surface faces the first leadframe. The semiconductor device further includes a second semiconductor die spaced laterally from the first semiconductor die and including a second active device formed therein, the second semiconductor die comprising a second upper surface and a second bottom surface opposite the second upper surface, the second semiconductor die electrically connected to a second leadframe and configured such that the second upper surface faces the second leadframe. The semiconductor device includes a conductive element electrically connecting the first and second semiconductor dies. The semiconductor device further includes first and second interconnect layers. The first interconnect layer is between the first upper surface and a first end of the conductive element, the first interconnect layer being configured to provide vertical separation and electrical connection between the first semiconductor die and the conductive element. The second interconnect layer is between the second upper surface and the second leadframe, the second interconnect layer being configured to provide vertical separation and electrical connection between the second semiconductor die and the second leadframe.

In accordance with an embodiment of the invention, a method of fabricating a semiconductor device including at least first and second series-connected semiconductor dies is provided. The method includes: providing a first semiconductor die including a first surface and a second surface opposite the first surface, the first semiconductor die including a first active device formed therein, the first active device comprising a first terminal on the first surface and a second terminal on the second surface; electrically connecting the second surface of the first semiconductor die to a first leadframe of the semiconductor device; providing a second semiconductor die including a third surface and a fourth surface opposite the third surface, the second semiconductor die including a second active device formed therein, the second active device comprising a third terminal on the third surface and a fourth terminal on the fourth surface; forming a first interconnect layer between the first surface of the first semiconductor die and the fourth surface of the second semiconductor die, the first interconnect layer being configured to provide vertical separation between the first and second semiconductor dies and to provide electrical connection between the first terminal of the first active device and the fourth terminal of the second active device; and forming a conductive element having a first end electrically connected to the third surface of the second semiconductor die and having a second end electrically connected to a second leadframe of the semiconductor device.

In accordance with another embodiment of the invention, a method of fabricating a semiconductor device including at least first and second series-connected semiconductor dies is provided. The method includes: providing a first semiconductor die including a first active device formed therein, the first semiconductor die comprising a first upper surface and a first bottom surface opposite the first upper surface; electrically connecting the first semiconductor die to a first leadframe of the semiconductor device, the first semiconductor die being configured such that the first bottom surface faces the first leadframe; providing a second semiconductor die spaced laterally from the first semiconductor die and including a second active device formed therein, the second semiconductor die comprising a second upper surface and a second bottom surface opposite the second upper surface; electrically connecting the second semiconductor die to a second leadframe of the semiconductor device, the second semiconductor die being configured such that the second upper surface faces the second leadframe; forming a conductive element electrically connecting the first and second semiconductor dies; forming a first interconnect layer between the first upper surface of the first semiconductor die and a first end of the conductive element, the first interconnect layer being configured to provide vertical separation and electrical connection between the first semiconductor die and the conductive element; and forming a second interconnect layer between the second upper surface of the second semiconductor die and the second leadframe, the second interconnect layer being configured to provide vertical separation and electrical connection between the second semiconductor die and the second leadframe.

As the term may be used herein, “facilitating” an action includes performing the action, making the action easier, helping to carry the action out, or causing the action to be performed. Thus, by way of example only and without limitation, in the context of a semiconductor fabrication process, instructions executing on one machine for performing a particular action in fabricating a semiconductor device might facilitate an action carried out by instructions executing on a different machine, such as by sending appropriate data or commands to cause or aid the action to be performed. For the avoidance of doubt, where an actor facilitates an action by other than directly performing the action, the action is nevertheless performed by some entity or combination of entities.

Techniques of the present invention can provide substantial beneficial technical effects. By way of example only and without limitation, techniques according to embodiments of the invention may provide one or more of the following advantages, among other benefits:
minimizes additional process steps, thereby reducing overall cost and fabrication complexity, as well as improving yield;
provides manufacturing margin for the application and control of conductive material between chip and leadframe/clip, thus improving yield and reliability;
provides Z offset between leadframe/clip and top surface of chip, thereby preventing the conductive material connecting those surfaces from extending to the die edge and causing an electrical short;
provides reduced package height compared to conventional designs;
provides minimized clip design complexity, cost and yield;
allows the use of identical chip design from same wafer and eliminates the need for a unique chip design for each component.

These and other features and advantages of the present invention will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a cross-sectional view depicting at least a portion of an exemplary semiconductor device, according to one or more embodiments of the present disclosure;

FIG. 2A is a cross-sectional view depicting at least a portion of an exemplary semiconductor device, according to another embodiment of the present disclosure;

FIG. 2B is a cross-sectional view depicting at least a portion of an exemplary semiconductor device which employs an alternative connection arrangement for electrically connecting the second semiconductor chip to a leadframe, according to one or more embodiments of the present disclosure;

FIG. 2C is a cross-sectional view depicting at least a portion of an exemplary semiconductor device which employs an alternative configuration to the illustrative semiconductor device shown in FIG. 2B, according to one or more embodiments of the present disclosure;

FIGS. 3A-3E are cross-sectional views conceptually depicting intermediate process steps in an exemplary method of fabricating the illustrative semiconductor device shown in FIG. 1, according to one or more embodiments of the present disclosure;

FIGS. 4A-4E are cross-sectional views conceptually depicting intermediate process steps in an exemplary method of fabricating the illustrative semiconductor device shown in FIGS. 2A and 2B, according to one or more embodiments of the present disclosure; and

FIG. 5 is a cross-sectional view depicting at least a portion of an exemplary semiconductor device which provides an external connection to an internal switching node of the first and second semiconductor chips, according to one or more embodiments of the present disclosure.

It is to be appreciated that elements in the figures are illustrated for simplicity and clarity. Common but well-understood elements that may be useful or necessary in a commercially feasible embodiment are not necessarily shown in order to facilitate a less hindered view of the illustrated embodiments.

### DETAILED DESCRIPTION

Principles of the present invention, as manifested in one or more embodiments thereof, will be described herein in the context of illustrative methods for fabricating a semiconductor device comprising multiple series-connected semiconductor chips therein. The novel semiconductor device fabrication methods, and the semiconductor devices formed thereby, according to embodiments of the present disclosure may be well-suited, for example, in power switching applications, such as, for example, voltage regulators or power converters (e.g., direct current (DC)-DC converters, alternating current (AC)-DC converters, etc.) and Schottky diodes, among other beneficial applications. It is to be appreciated, however, that the present inventive concepts are not limited to the specific structures and/or methods illustratively shown and described herein. Rather, it will become apparent to those skilled in the art given the teachings herein that numerous modifications can be made to the embodiments shown that are within the scope of the claimed invention. That is, no limitations with respect to the embodiments shown and described herein are intended or should be inferred.

Reference may be made herein to “exemplary” embodiments, devices, circuits, methods, etc. As used herein, the term “exemplary” is intended to mean “serving as an example, illustration, instance or explanation,” and is not intended to imply that a particular embodiment, device, circuit, method, etc., serves as a model to be accurately copied. In other words, any embodiment, device, circuit, method, etc., described herein as being “exemplary” should not necessarily be interpreted as being preferable or advantageous over other embodiments, devices, circuits, methods, etc., within the scope of the present disclosure.

As previously stated, power switching applications and the like often employ a pair of vertical conduction devices (e.g., Schottky diodes, metal-oxide-semiconductor field-effect transistors (MOSFETs), insulated gate bipolar transistors (IGBTs), etc.) connected together in a series configuration and integrated in a semiconductor package. In most instances, the pair of vertical devices are disposed on a ceramic substrate, which is costly to manufacture, and may have other disadvantages, such as, for example, poor heat dissipation, parasitic inductance, etc. Embodiments of the present disclosure provide an improved method for serially connecting two or more vertical conduction devices and integrating the devices into a single semiconductor package.

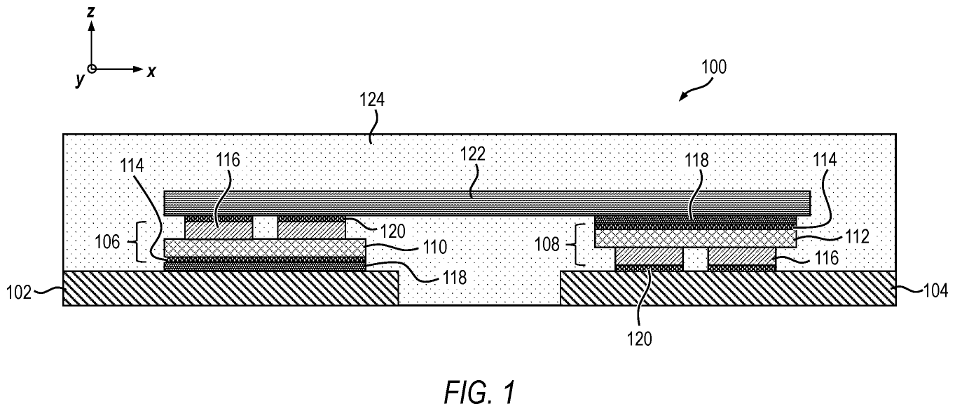

FIG. 1 is a cross-sectional view depicting at least a portion of an exemplary semiconductor device 100, according to one or more embodiments of the present disclosure. With reference to FIG. 1, the semiconductor device 100 includes a first leadframe 102 and a second leadframe 104, on which a first semiconductor structure 106 and a second semiconductor structure 108, respectively, are arranged. The first and second leadframes 102, 104, which are separated laterally from one another (e.g., in an x-axis and/or y-axis direction), may be formed of a conductive material, such as a metal (e.g., copper) or metal compound, although embodiments are not limited to any specific material(s) for forming the leadframes. Furthermore, the first and second leadframes need not be formed of the same material. The first and second leadframes 102, 104 may form external electrical connections of the semiconductor device 100.

Although described as independent structures herein, it is to be appreciated that the first and second leadframes 102, 104 are generally formed as distinct portions of the same leadframe. However, while the first and second leadframes 102, 104 may be physically part of the same leadframe structure, from a practical standpoint they may be at different voltage potentials. It is contemplated that in some embodiments, the first and second leadframes 102, 104 may also be physically separated from one another.

The first semiconductor structure 106 may comprise a first semiconductor chip (i.e., die) 110 having an active device formed therein. In one or more embodiments, the active device formed on the first semiconductor chip 110 may include, for example, a vertical transistor device (e.g., a vertical MOSFET), a diode (e.g., Schottky diode), or the like. A vertical MOSFET typically includes a drain terminal on a back surface of the device and gate and source terminals on an upper (i.e., front or top) surface of the device. Likewise, the second semiconductor structure 108 may comprise a second semiconductor chip (i.e., die) 112 having an active device formed therein. The active device formed on the second semiconductor chip 112 may include, for example, a vertical transistor device (e.g., vertical MOSFET), diode, or the like. In some embodiments, the first and second semiconductor chips may be identical to one another, although in other embodiments the first and second semiconductor chips may be different.

Each of the first and second semiconductor chips 110, 112 may include a backside conductive material layer 114, such as a metal (e.g., copper) or metal compound, on the back (i.e., bottom) surface of the chip. Although the backside conductive material layer 114 is shown as a single layer of material extending laterally (in a horizontal or x-axis direction) across the entire bottom surface of the semiconductor chips 110, 112, in some embodiments the backside conductive material layer 114 may be formed as a plurality of smaller conductive layers on the back surface of the semiconductor chips 110, 112. The backside conductive material layer 114 may form a terminal of the active device, such as a drain terminal in the case of a vertical MOSFET or a cathode terminal in the case of a diode, to provide electrical connection to the active device.

The semiconductor device 100 further includes an interconnect layer 116, which may be referred to hereinafter as a “bump” layer. The bump layer 116, in this illustrative embodiment, may be disposed on the upper (i.e., front or top) surface of each of the first and second semiconductor chips 110, 112, opposite the back surface of the first and second semiconductor chips 110, 112. The bump layer 116 acts as a standoff, providing a physical space (i.e., separation) between a semiconductor chip 110, 112 and a conductive element (e.g., leadframe, another semiconductor chip, etc.) to which the semiconductor chip is connected, which may prevent electrical shorting between active device terminals (or other conductive elements) on the front surface of the first and/or second semiconductor chip 110, 112 when the chip is brought into close contact with either the leadframe 102, 104 or a conductor (e.g., conductive clip 122, described in further detail below) used to connect the first semiconductor chip 110 to the second semiconductor chip 112.

The bump layer 116, which may comprise a conductive material, such as a metal (e.g., copper) or metal compound, may be formed (e.g., patterned) on one or more terminals of the active device, for example a source terminal in the case of a vertical MOSFET or an anode terminal in the case of a diode, for providing electrical connection to the active device, in addition to physical separation. Although the bump layer 116 is shown in FIG. 1 as comprising a plurality of separate conductive structures, in some embodiments, the bump layer 116 of a given semiconductor chip 110, 112 may be formed as a single (i.e., continuous) layer of conductive material extending laterally across the upper surface of the semiconductor chip.

The first semiconductor structure 106 may be stacked on at least a portion of an upper surface of the first leadframe 102 in a vertical (i.e., z-axis) direction. The backside conductive material layer 114 of the first semiconductor chip 110 may be electrically connected to the first leadframe 102 through an electrical connection layer 118 disposed between the upper surface of the first leadframe 102 and a bottom surface the backside conductive material layer 114 of the first semiconductor chip 110. The term “connected,” as may be used herein, is broadly intended to include an electrical and/or physical connection, and may include other intervening elements. The electrical connection layer 118 may comprise solder (e.g., tin/lead (Sn/Pb) or tin/silver (Sn/Ag) based alloys) or another conductive material (e.g., conductive epoxy). The electrical connection layer 118 may also serve as an attachment means for affixing the first semiconductor structure 106 to the first leadframe 102.

In some embodiments, the electrical connection layer 118 may comprise other materials that do not necessarily fall into the same categories as solder or epoxy. Such materials may include, but are not limited to, sintered metal (e.g., silver) or other hybrid materials. As will be known by those skilled in the art, sintering is a process that involves heating (and/or compacting) the silver or other metal at a relatively low temperature, without melting the material to the point of liquefaction.

The second semiconductor structure 108 may be stacked on at least a portion of an upper surface of the second leadframe 104 in the vertical (i.e., z-axis) direction. To facilitate a series connection between the first and second semiconductor chips 110, 112, the second semiconductor structure 108 may be flipped upside down, in the vertical direction, so that the bump layer 116 of the second semiconductor chip 112 is facing the second leadframe 104. The bump layer 116 of the second semiconductor chip 112 may be electrically connected to the second leadframe 104 through an electrical connection layer 120 disposed between the upper surface of the second leadframe 104 and an upper surface the bump layer 116 of the second semiconductor chip 112. The electrical connection layer 120 may comprise solder or solder paste (e.g., Sn/Pb or Sn/Ag based alloy) or another conductive material (e.g., conductive epoxy). The electrical connection layer 120, which may comprise the same material of as the electrical connection layer 118, preferably serves as an attachment means for affixing the second semiconductor structure 108 to the second leadframe 104.

As previously stated in conjunction with the electrical connection layer 118, the electrical connection layer 120 may comprise other materials that do not necessarily fall into the same categories as solder or epoxy. Such materials may include, for example, sintered silver or other hybrid materials, although embodiments of the present disclosure are not limited thereto.

The backside conductive material layer 114 of the second semiconductor structure 108 may be connected to the bump layer 116 of the first semiconductor structure 106 through an electrically conductive clip 122 or other conductive element. The clip 122 may comprise a metal (e.g., copper) or metal compound, or an alternative conductive material. The bump layer 116 of the first semiconductor structure 106 may be electrically connected to the clip 122 through the electrical connection layer 120 disposed between the upper surface of the bump layer 116 of the first semiconductor structure 106 and a first end portion of the clip 122. The backside conductive material layer 114 of the second semiconductor structure 108 may be electrically connected to the clip 122 through the electrical connection layer 118 disposed between the bottom surface the backside conductive material layer 114 of the second semiconductor structure 108 and a second end portion of the clip 122, the second end portion being laterally opposite the first end portion of the clip 122. In this manner, the first and second semiconductor chips 110, 112 are electrically connected together in a series configuration.

In some embodiments, for example when sintering is used in place of solder or epoxy for the electrical connection layer 118 or 120, the conductive clip 122 may be directly attached to the first and/or second semiconductor chips 110, 112, and therefore the electrical connection layers 118, 120 would essentially comprise the sintered silver or other metal.

In the illustrative semiconductor device 100, the first and second semiconductor structures 106, 108 may be arranged such that an upper surface of the electrical connection layer 120 of the first semiconductor structure 106 is coplanar with back surface of the electrical connection layer 118 of the second semiconductor structure 108. That is, a height, in the vertical (z-axis) direction, of the first semiconductor structure 106 and the electrical connection layers 118, 120 and bump layer 116 associated therewith may be the same (or nearly the same) as the height of the second semiconductor structure 108 and the electrical connection layers 118, 120 and bump layer 116 associated therewith.

In one or more embodiments, the semiconductor device 100 may include a molding compound 124 encapsulating or otherwise surrounding the first semiconductor structure 106, the second semiconductor structure 108, the first and second leadframes 102, 104, and the conductive clip 122, to thereby form a packaged semiconductor device. The term “surrounding” (or “surrounds,” or like terms) as may be used herein is intended to broadly refer to an element, structure or layer that extends around, envelops, encircles, or encloses another element, structure or layer on all sides, although breaks or gaps may also be present. Thus, for example, a material layer having voids therein may still “surround” another layer which it encircles.

The molding compound 124 preferably comprises an insulating material, such as an insulating epoxy. In one or more embodiments, the molding compound 124 may comprise material having high thermal conductivity, which may facilitate the dissipation of heat generated in the first and second semiconductor chips 110, 112. It is to be understood that the molding compound 124 need not entirely encapsulate the structures forming the semiconductor device 100; that is, it is contemplated that voids or spaces may be present in the molding compound 124. Alternatively, an interior space defined by sidewalls, a bottom and a top of the device package may be left unfilled with molding compound 124.

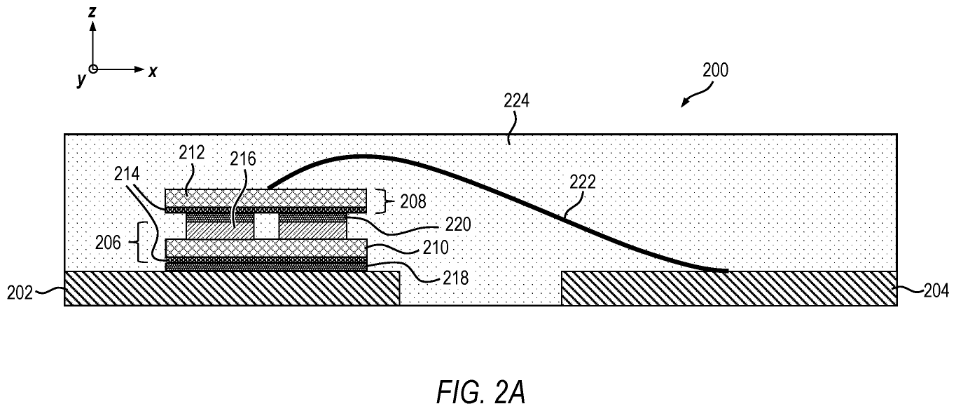

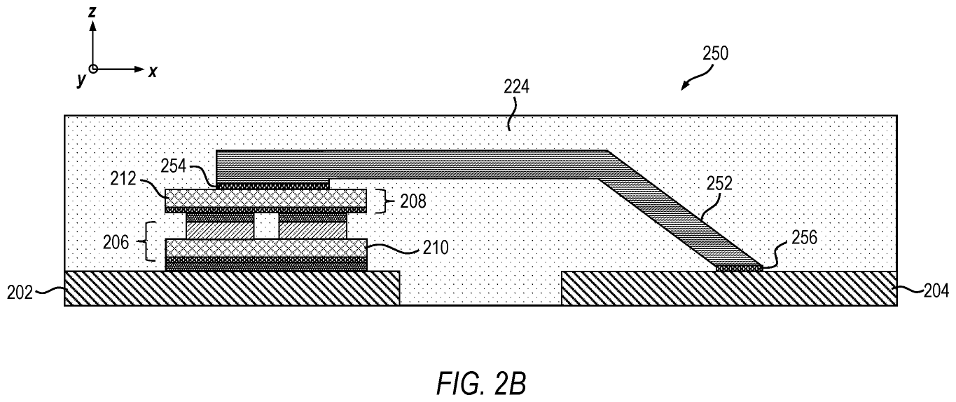

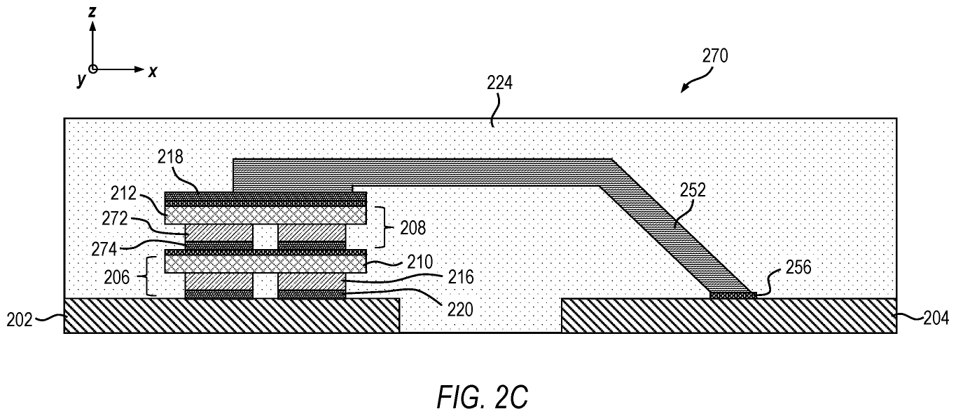

FIG. 2A is a cross-sectional view depicting at least a portion of an exemplary semiconductor device 200, according to another embodiment of the present disclosure. With reference to FIG. 2A, the semiconductor device 200 includes a first leadframe 202 and a second leadframe 204. The first and second leadframes 202, 204, which are separated laterally (i.e., horizontally) from one another (e.g., in an x-axis and/or y-axis direction), may be formed of a conductive material, such as a metal (e.g., copper) or metal compound, although embodiments are not limited to any specific material(s) for forming the leadframes. Furthermore, the first and second leadframes need not be formed of the same material. The first and second leadframes 202, 204 may form external electrical connections of the semiconductor device 200.

Consistent with the description of the first and second leadframes 102, 104 shown in FIG. 1, although described as independent structures herein, it is to be appreciated that the first and second leadframes 202, 204 are generally formed as distinct portions of the same leadframe. However, while the first and second leadframes 202, 204 may be physically part of the same leadframe structure, from a practical perspective they may be at different voltage potentials. It is contemplated that in some embodiments, the first and second leadframes 202, 204 may also be physically separated from one another.

The semiconductor device 200 further includes a first semiconductor structure 206 and a second semiconductor structure 208, which in this illustrative embodiment may be sequentially stacked in a vertical (i.e., z-axis) direction on the first leadframe 202. The first semiconductor structure 206 may comprise a first semiconductor chip 210 having an active device formed therein. In one or more embodiments, the active device formed in the first semiconductor chip 210 may include, for example, a vertical transistor device (e.g., a vertical MOSFET), a diode (e.g., Schottky diode), or the like. A vertical MOSFET typically includes a drain terminal on a back (i.e., bottom or lower) surface of the device and gate and source terminals on an upper (i.e., front or top) surface of the device. Likewise, the second semiconductor structure 208 may comprise a second semiconductor chip 212 having an active device formed therein. The active device formed in the second semiconductor chip 212 may include, for example, a vertical transistor device (e.g., vertical MOSFET), diode, or the like. In some embodiments, the first and second semiconductor chips may be identical to one another, although in other embodiments the first and second semiconductor chips may be different.

Each of the first and second semiconductor chips 210, 212 may include a backside conductive material layer 214, such as a metal (e.g., copper) or metal compound, on the back surface of the chip. Although the backside conductive material layer 214 is shown as a single layer of material extending laterally (in a horizontal or x-axis direction) across the entire bottom surface of the semiconductor chips 210, 212, in some embodiments the backside conductive material layer 214 may be formed as a plurality of smaller conductive layers on the back surface of the semiconductor chips 210, 212. The backside conductive material layer 214 may form a terminal of the active device, such as a drain terminal in the case of a vertical MOSFET or a cathode terminal in the case of a diode, to provide electrical connection to the active device.

The semiconductor device 200 further includes an interconnect layer 216, which may be referred to hereinafter as a “bump” layer. The bump layer 216, in this illustrative embodiment, may be disposed on the upper (i.e., front or top) surface of the first and/or second semiconductor chips 210, 212, opposite the back surface of the first and/or second semiconductor chips 210, 212. The bump layer 216, in a manner similar to the bump layer 116 shown in FIG. 1, acts as a standoff for providing a physical space between the first and second semiconductor chips 210, 212 to thereby prevent electrical shorting between active device terminals (or other conductive elements) on the front surface of the first semiconductor chip 210 when the first semiconductor chip 210 is connected with the second semiconductor chip 212.

The bump layer 216 may be formed as a conductive standoff comprising, for example, a metal (e.g., copper) or metal compound. In one or more embodiments, the bump layer 216, which comprises conductive material, may be patterned on one or more terminals of the active device, for example a source terminal in the case of a vertical MOSFET or an anode terminal in the case of a diode, for providing electrical connection to the active device. In some embodiments, the bump layer 216 may comprise solder bumps. Although the bump layer 216 is shown in FIG. 2A as comprising a plurality of separate terminals, in some embodiments, the bump layer 216 may be formed as a single (i.e., continuous) layer of conductive material extending laterally across the upper surface of the semiconductor chip.

The first semiconductor structure 206 may be stacked on at least a portion of an upper surface of the first leadframe 202 in the vertical (i.e., z-axis) direction. The backside conductive material layer 214 of the first semiconductor structure 206 may be electrically connected to the first leadframe 202 through an electrical connection layer 218 disposed between the upper surface of the first leadframe 202 and a bottom surface the backside conductive material layer 214 of the first semiconductor structure 206. The electrical connection layer 218 may comprise, for example, solder (e.g., tin/lead (Sn/Pb) or tin/silver (Sn/Ag) based alloys) or another conductive material (e.g., conductive epoxy). The electrical connection layer 218 may also serve as an attachment means for affixing the first semiconductor structure 206 to the first leadframe 202.

Unlike the illustrative semiconductor device 100 shown in FIG. 1 wherein the first and second semiconductor structures 106, 108 are laterally adjacent to (and separated from) one another, the semiconductor device 200 of FIG. 2A may be configured such that the second semiconductor structure 208 is stacked vertically (i.e., in the z-axis direction) above the first semiconductor structure 206, so that the second semiconductor structure 208 at least partially overlaps the first semiconductor structure 206 in a plan view (i.e., an x-axis and/or y-axis direction). Specifically, the backside conductive material layer 214 of the second semiconductor structure 208 may be electrically connected to the bump layer 216 of the first semiconductor structure 206 through an electrical connection layer 220 disposed between an upper surface of the bump layer 216 of the first semiconductor structure 206 and a bottom surface of the backside conductive material layer 214 of the second semiconductor structure 208. The electrical connection layer 220 may comprise, for example, solder (e.g., tin/lead (Sn/Pb) or tin/silver (Sn/Ag) based alloys) or another conductive material (e.g., conductive epoxy), although embodiments are not limited thereto. The electrical connection layer 220 may also serve as an attachment means for affixing the second semiconductor structure 208 to the first semiconductor structure 206. Thus, the first and second semiconductor chips 210, 212 may be electrically connected in series with one another through the bump layer 216 of the first semiconductor structure 206, the electrical connection layer 220, and the backside conductive material layer 214 of the second semiconductor structure 208, without the need for a separate conductive clip (e.g., 122 in FIG. 1) or other connection arrangement.

Electrical connection between the second semiconductor chip 212 and the second leadframe 204 may be provided using a wire connection 222, such as a bond wire or other conductive element. In one or more embodiments, the wire connection 222 may comprise a metal (e.g., copper or gold) or another low-resistance conductive material, although embodiments of the invention are not limited to any specific material for forming the wire connection 222. A conductive pad (not explicitly shown, but implied) may be provided on an upper surface of the second semiconductor chip 212 configured to receive a first end of the wire connection 222. A second end of the wire connection 222, opposite the first end, may be attached to the second leadframe 204. The respective ends of the wire connection 222 may be attached to the corresponding structures using a wire bonding process or the like, as will be known by those skilled in the art.

In one or more embodiments, the semiconductor device 200 may include a molding compound 224 encapsulating the first semiconductor structure 206, the second semiconductor structure 208, the first and second leadframes 202, 204, the electrical connection layers 218, 220, and the wire connection 222, to thereby form a packaged semiconductor device. The molding compound 224 preferably comprises an insulating material, such as an insulating epoxy. It is to be understood that the molding compound 224 need not entirely encapsulate the structures forming the semiconductor device 200; that is, it is contemplated that voids or spaces may be present in the molding compound 224. Alternatively, an interior space defined by sidewalls, a bottom and a top of the device package may be left unfilled with molding compound 224.

Rather than using a wire bond connection 222 to electrically connect the second semiconductor chip 212 to the second leadframe 204 as shown in FIG. 2A, an alternative connection arrangement may be employed, for example as shown in FIG. 2B. Specifically, FIG. 2B is a cross-sectional view depicting at least a portion of an exemplary semiconductor device 250 which employs a conductive clip 252 or other conductive element for electrically connecting the second semiconductor chip 212 to the second leadframe 204, according to one or more embodiments of the present disclosure. The conductive clip 252 may comprise a metal (e.g., copper) or metal compound, or an alternative conductive material.

A first end portion of the conductive clip 252 may be connected to an upper surface of the second semiconductor chip 212 through an electrical connection layer 254 disposed between the upper surface of the second semiconductor chip 212 and a bottom surface of the first end portion of the conductive clip 252. A second end portion of the conductive clip 252, the second end portion being laterally opposite the first end portion of the clip 252, may be connected to the upper surface of the second leadframe 204 through an electrical connection layer 256 disposed between the upper surface of the second leadframe 204 and a bottom surface of the second end portion of the conductive clip 252. In this manner, the first and second semiconductor chips 210, 212 may be electrically connected together in a series configuration.

In one or more embodiments, the semiconductor device 250 may include the molding compound 224 extending around or encapsulating (i.e., surrounding) the first semiconductor structure 206, the second semiconductor structure 208, the first and second leadframes 202, 204, the electrical connection layers 218, 220, and the conductive clip 252, to thereby form the packaged semiconductor device 250.

FIG. 2C is a cross-sectional view depicting at least a portion of an exemplary semiconductor device 270 which employs an alternative configuration compared to the illustrative semiconductor device 250 shown in FIG. 2B, according to one or more embodiments of the inventive concept. Specifically, in the semiconductor device 270 of FIG. 2C, the first and second semiconductor chips 210, 212 are flipped upside down and oriented so that their upper surfaces are facing the first leadframe. The semiconductor device 270 further includes a second interconnect layer 272 (i.e., bump layer) disposed between the first and second semiconductor ships 210, 212.

With reference to FIG. 2C, the first semiconductor structure 206 comprises the first semiconductor chip 210 and a first bump layer 216 formed on the upper surface of the first semiconductor chip 210. The first semiconductor structure 206 is flipped upside down and oriented such that the upper surface of the first semiconductor chip 210, having the first bump layer 216 thereon, is facing the first leadframe 202. The first bump layer 216 is connected (electrically and physically) to the first leadframe 202 via a first electrical connection layer 220 disposed on the upper surface of the first bump layer 216. The first electrical connection layer 220 may comprise, for example, solder (e.g., tin/lead (Sn/Pb) or tin/silver (Sn/Ag) based alloys) or another conductive material (e.g., conductive epoxy), although embodiments are not limited thereto.

Similarly, the second semiconductor structure 208 comprises the second semiconductor chip 212 and a second bump layer 272 formed on the upper surface of the second semiconductor chip 212. The second semiconductor structure 208, like the first semiconductor structure 206, is flipped upside down and oriented such that the upper surface of the second semiconductor chip 212, having the second bump layer 272 thereon, is facing the back surface of the first semiconductor chip 210. The second bump layer 272 is connected (electrically and physically) to the back surface of the first semiconductor chip 210 via a second electrical connection layer 274 disposed on the upper surface of the second bump layer 272. The second electrical connection layer 274 may comprise, for example, solder (e.g., tin/lead (Sn/Pb) or tin/silver (Sn/Ag) based alloys) or another conductive material (e.g., conductive epoxy), although embodiments are not limited thereto; the second electrical connection layer 274 may comprise material that is different than the first electrical connection layer 220.

The semiconductor device 270, like the illustrative semiconductor device 250 depicted in FIG. 2B, may utilize a conductive clip 252 for providing electrical connection between the second semiconductor chip 212 and the second leadframe 204. The first end portion of the conductive clip 252 may be connected to the back surface of the second semiconductor chip 212 through an electrical connection layer 218 disposed between the back surface of the second semiconductor chip 212 and a bottom surface of the first end portion of the conductive clip 252. The second end portion of the conductive clip 252 may be connected to the upper surface of the second leadframe 204 through an electrical connection layer 256 disposed between the upper surface of the second leadframe 204 and a bottom surface of the second end portion of the conductive clip 252, as previously described. In this manner, the first and second semiconductor chips 210, 212 may be electrically connected together in a series configuration.

In one or more embodiments, the semiconductor device 270 may include the molding compound 224 extending around or encapsulating (i.e., surrounding) the first semiconductor structure 206, the second semiconductor structure 208, the first and second leadframes 202, 204, the electrical connection layers 218, 220, and the conductive clip 252, to thereby form the packaged semiconductor device 270.

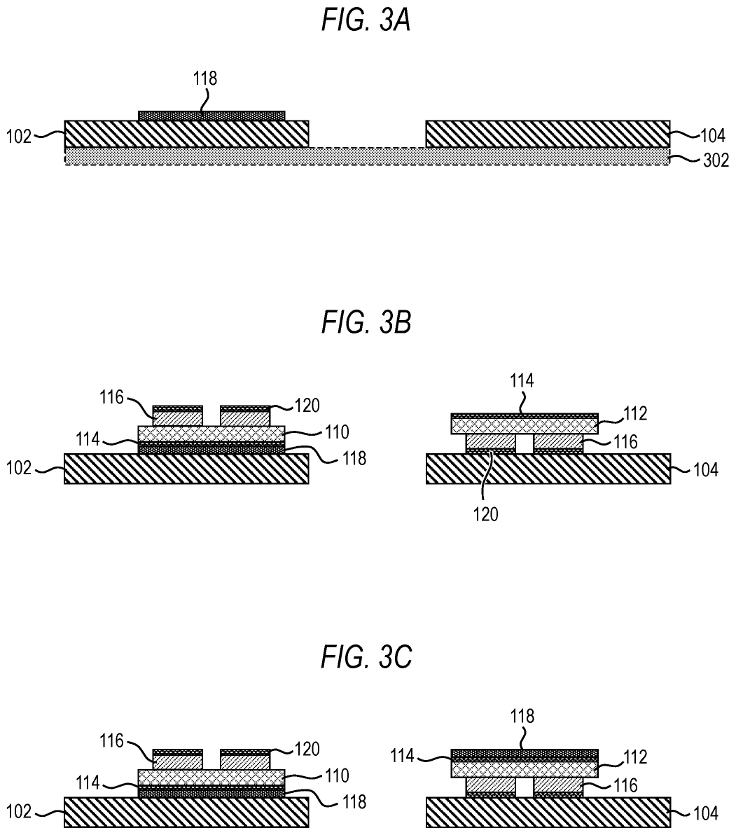

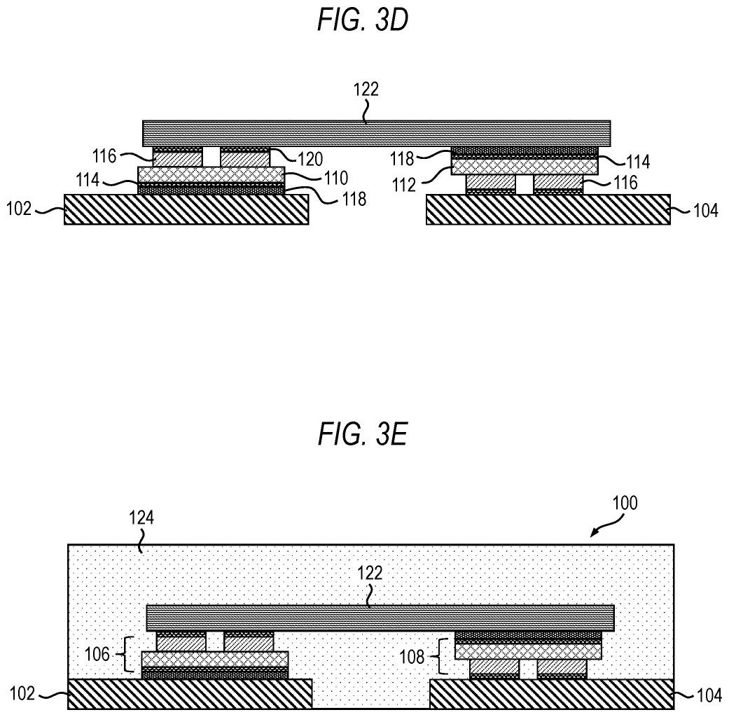

FIGS. 3A-3E are cross-sectional views conceptually depicting intermediate process steps in an exemplary method of fabricating the illustrative semiconductor device 100 shown in FIG. 1, according to one or more embodiments of the present disclosure.

Although the overall fabrication methods and the structures formed thereby are entirely novel, certain individual processing steps required to implement methods according to embodiments of the present disclosure described herein may utilize conventional semiconductor fabrication techniques and conventional semiconductor fabrication tooling. These techniques and tooling will already be familiar to those having ordinary skill in the relevant art given the teachings herein. Moreover, many of the processing steps and tooling used to fabricate semiconductor devices are also described in a number of readily available publications, including, for example: P. H. Holloway et al., Handbook of Compound Semiconductors: Growth, Processing, Characterization, and Devices, Cambridge University Press, 2008; and R. K. Willardson et al., Processing and Properties of Compound Semiconductors, Academic Press, 2001, which are both hereby incorporated herein by reference in their entireties for all purposes. It is emphasized that while some individual processing steps are set forth herein, those steps are merely illustrative, and one skilled in the art may be familiar with several equally suitable alternatives that would also fall within the scope of the inventive concept.

It is to be appreciated that the various layers and/or regions that may be shown in the accompanying figures are not necessarily drawn to scale. Furthermore, one or more semiconductor layers of a type commonly used in fabricating such semiconductor devices may not be explicitly shown in a given figure in order to facilitate a clearer description. This does not imply that the semiconductor layer(s) not explicitly shown are omitted in the actual device.

With reference to FIG. 3A, first and second leadframes 102 and 104, respectively, are provided. The first and second leadframes 102, 104 may be supported on a substrate 302 or other carrier during processing; the substrate 302 may be removed during subsequent processing. The first and second leadframes 102, 104 may comprise a metal (e.g., copper) or a metal compound, although embodiments are not limited to any specific material for forming the leadframes. A first material deposition process (e.g., metal deposition) may then be performed in which a layer of conductive material is deposited onto at least a portion of the upper surface of the first leadframe 104 to form the electrical connection layer 118. In one or more embodiments, the conductive material comprises solder (e.g., Sn/Pb or Sn/Ag based alloys), or a conductive epoxy, although embodiments of the invention are not limited to any specific conductive material forming the electrical connection layer 118.

Metal deposition generally describes any additive fabrication process whereby a metal is layered (i.e., deposited) onto some other material such as metals, ceramics, and even plastics. The manner in which the metal is deposited onto the surface can vary greatly, and may include, for example, chemical vapor deposition (CVD), plasma-enhanced chemical vapor deposition (PECVD), physical vapor deposition (PVD), molecular beam epitaxy (MBE), electron beam physical vapor deposition (EBPVD), laser metal deposition (LMD), direct metal deposition (DMD), electroplating, etc., as will be known by those skilled in the art, although embodiments are not limited to any specific material deposition technique. In the case where the electrical connection layer 118 comprises a conductive epoxy, the epoxy may be deposited onto the surface of the first leadframe 102 through dispensing via time-pressure, auger, printing (e.g., screen printing), or jetting, and through daubing or pin transfer, although embodiments are not limited thereto.

In FIG. 3B, the first and second semiconductor structures (106 and 108 in FIG. 1) are placed on and attached to the first and second leadframes 102, 104, respectively. As previously described in conjunction with FIG. 1, the first semiconductor structure (106 in FIG. 1) may include the first semiconductor chip (i.e., die) 110, backside conductive material layer 114, such as a metal (e.g., copper) or metal compound, formed on the back (i.e., bottom) surface of the first semiconductor chip 110, and bump layer 116 formed on the upper (i.e., front or top) surface of the first semiconductor chip 110. The bump layer 116 may comprise a conductive material, such as a metal (e.g., copper) or metal compound. The electrical connection layer 118 disposed between the bottom surface of the backside conductive material layer 114 on the first semiconductor chip 110 and the upper surface of the first leadframe 102, is used to attach the first semiconductor chip 110 to the first leadframe 102. Likewise, the second semiconductor structure (108 in FIG. 1) may include the second semiconductor chip (i.e., die) 112, backside conductive material layer 114, such as a metal (e.g., copper) or metal compound, formed on the back (i.e., bottom) surface of the second semiconductor chip 112, and bump layer 116 formed on the upper (i.e., front or top) surface of the second semiconductor chip 112.

The first semiconductor structure may be placed on the first leadframe 102 so that the back surface of the backside conductive material layer 114 of the first semiconductor structure is facing the upper surface of the first leadframe 102. The second semiconductor structure may be flipped upside down on the second leadframe 104 so that the upper surface of the bump layer 116 is facing the upper surface of the second leadframe 104. The electrical connection layer 120 of the second semiconductor structure is disposed between the upper surface of the second leadframe 104 and the upper surface the bump layer 116 of the second semiconductor chip 112.

In some embodiments, one or more of the electrical connection layers 118, 120 may comprise solder paste (e.g., Sn/Pb or Sn/Ag based alloys), in which case a solder reflow process is performed to attach the first and/or second semiconductor structures to their corresponding first and/or second leadframes 102, 104. The attachment process for affixing the first semiconductor structure to the first leadframe 102 may be the same as the attachment process used to attach the second semiconductor structure to the second leadframe 104, although the first and second semiconductor structures may employ different attachment processes. During solder reflow, a solder paste may be deposited onto a surface (e.g., the upper surface of the first leadframe 102) through dispensing, which can be through time-pressure, auger pump, printing (e.g., screen printing), jetting, etc. When dispensed onto the surface, the solder will spread out slightly due to flux included in the solder paste. When the solder is brought up to its reflow (i.e., molten) temperature, it will flow and create a bond between the first leadframe 102 and the electrical connection layer 118 on the back surface of the first semiconductor chip 110 and/or between the second leadframe 104 and the electrical connection layer 120 on the upper surface of the bump layer 116 of the second semiconductor chip 112. Because the solder forming the electrical connection layer 118, 120 is conductive, the bond between the first semiconductor chip 110 and the first leadframe 102 and/or between the second semiconductor chip 112 and the second leadframe 104 will be electrical, thermal and mechanical in nature.

Alternatively, in other embodiments the electrical connection layer 118, 120 may comprise a conductive epoxy and therefore an epoxy attach (or thermal cure epoxy attach) process may be performed. The epoxy attach process may involve applying a bed of conductive epoxy to the upper surface of the first leadframe 102 and/or the back surface of the backside conductive material layer 114 on the first semiconductor chip 110 and placing the first semiconductor structure on the first leadframe 102, and/or applying a bed of conductive epoxy to the upper surface of the second leadframe 104 and/or the upper surface of the bump layer 116 on the second semiconductor chip 112 and placing the second semiconductor structure on the second leadframe 104. In general, epoxy can be deposited onto a surface through dispensing via time-pressure, auger, printing (e.g., screen printing), or jetting, and through daubing or pin transfer. The conductive epoxy is then cured, such as by applying heat or an alternative energy source (e.g., ultraviolet (UV) light) to form a thermal, electrical and mechanical connection/bond between the first semiconductor chip 110 and the first leadframe 102 and/or between the second semiconductor chip 112 and the second leadframe 104. Solder paste generally reflows at high temperatures compared to the curing of epoxies, and thus an epoxy cure attachment process may be preferred for certain applications having a lower thermal budget.

As shown in FIG. 3C, a second material deposition process (e.g., metal deposition) may be performed in which a layer of conductive material is deposited on the back surface of the backside conductive material layer 114 on the second semiconductor chip 112 to form the electrical connection layer 118 on the second semiconductor structure. In one or more embodiments, the second material deposition process may be consistent with the first material deposition process described in conjunction with FIG. 3A. The deposited conductive material may comprise a metal (e.g., copper), or a metal compound, although embodiments of the invention are not limited to any specific conductive material forming the electrical connection layer 118. The second material deposition process may be performed, for example, using CVD, PECVD, PVD, MBE, EBPVD, LMD, DMD, etc., although embodiments are not limited to any specific material deposition technique. In one or more embodiments, the second material deposition process may involve depositing a bed of solder, solder paste or conductive epoxy on the back surface of the backside conductive material layer 114 on the second semiconductor chip 112 using techniques consistent with those previously described in connection with FIG. 1.

It is to be appreciated that in some embodiments, the first and second semiconductor structures may be provided with the electrical connection layers 118, 120 already formed on their respective surfaces; for example, the electrical connection layer 120 formed on the upper surface of the bump layer 116 and electrical connection layer 118 formed on the back surface of the backside conductive material layer 114 of the first semiconductor structure, and the electrical connection layer 118 formed on the back surface of the backside conductive material layer 114 and the electrical connection layer 120 formed on the upper surface of the bump layer 116 of the second semiconductor structure. In this scenario, the first and second material deposition steps shown in FIGS. 3A and 3C, respectively, may be omitted. The first and second semiconductor structures may then be attached to the first and second leadframes 102, 104 using the techniques previously described in conjunction with FIG. 3B and the process flow would continue as described subsequently. This approach may beneficially afford a simplified fabrication process flow.

Continuing with FIG. 3D, an electrically conductive clip 122 or other connection arrangement may be formed on the first and second semiconductor structures. Specifically, a first end of the conductive clip 122 is placed over the upper surface of the electrical connection layer 120 disposed on the first semiconductor structure and a second end of the conductive clip 122, laterally opposite the first end, is placed over the back surface of the electrical connection layer 118 disposed on the second semiconductor structure. An attachment process may then be performed to form an electrical and physical connection between the conductive clip 122 and the respective first and second semiconductor structures. For example, when one or more of the electrical connection layers 118, 120 comprises solder or solder paste (e.g., Sn/Pb or Sn/Ag based alloy), a solder reflow process may be used for electrically and physically bonding the electrical connection layers 118, 120 to the conductive clip 122. Alternatively or in addition, when one or more of the electrical connection layers 118, 120 comprises a conductive epoxy, an epoxy cure process may be used for electrically and physically bonding the electrical connection layers 118, 120 to the conductive clip 122.

As previously explained in conjunction with FIG. 1, the conductive clip 122 may comprise a metal (e.g., copper) or metal compound, or an alternative conductive material. Embodiments of the present disclosure are not limited to any specific material forming the conductive clip 122. In this manner, the first and second semiconductor chips 110, 112 may be electrically connected together in a series configuration.

The first and second semiconductor chips 110, 112, along with their respective electrical connection layers and conductive clip 122, may be encapsulated, as shown in FIG. 3E. Specifically, the molding compound 124 may be formed to surround (i.e., extend around) the first and second leadframes 102, 104, the first and second semiconductor chips 110, 112 and their respective electrical connection elements 116, 118, 120, and the conductive clip 122, to form the packaged semiconductor device 100. With the first and second semiconductor chips 110, 112 spaced laterally from one another so that upper surfaces of the first and second semiconductor structures are essentially coplanar with one another when viewed in cross-section, the semiconductor device 100 will have a thinner overall cross-sectional profile (i.e., height) compared to the exemplary semiconductor device 200 shown in FIG. 2A in which the first and second semiconductor chips 110, 112 are vertically stacked relative to one another.

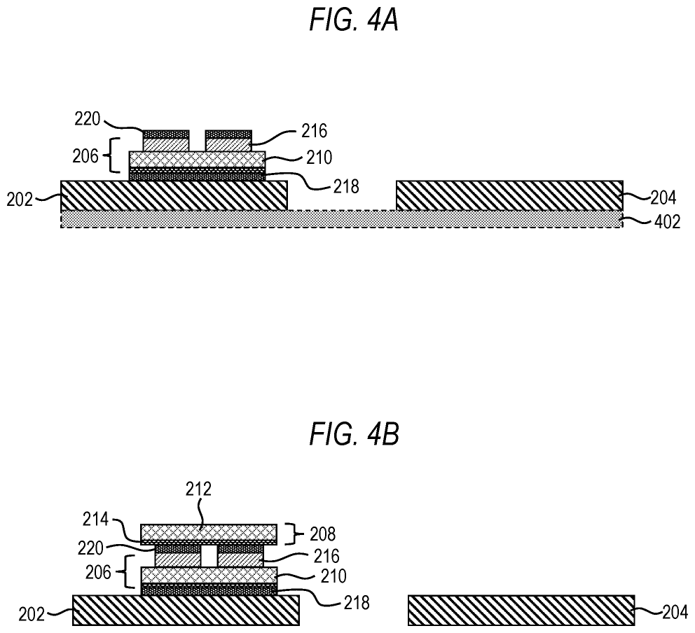

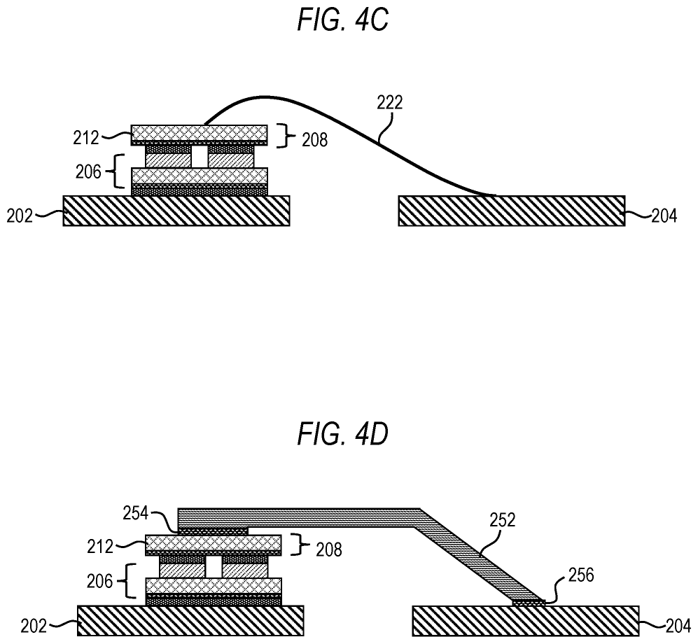

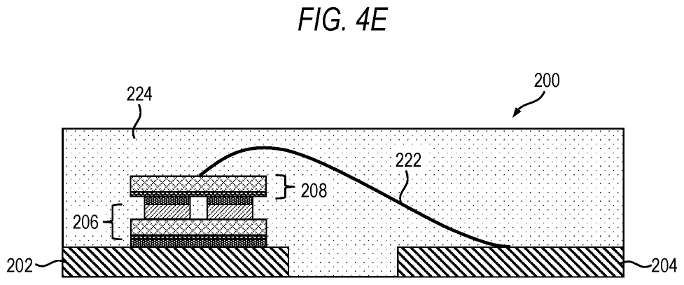

FIGS. 4A-4E are cross-sectional views conceptually depicting intermediate process steps in an exemplary method of fabricating the illustrative semiconductor devices 200 and 252 shown in FIGS. 2A and 2B, respectively, according to one or more embodiments of the present disclosure. With reference to FIG. 4A, first and second leadframes 202 and 204, respectively, are provided. The first and second leadframes 202, 204 may be at least temporarily supported on a substrate 402 or other carrier during processing; the substrate 402 may be removed during subsequent processing.

The first semiconductor structure 206 may be placed on the upper surface of the first leadframe 202, with the back surface of the first semiconductor structure 206 facing down towards the upper surface of the first leadframe 202. The first semiconductor structure 206 may comprise the first semiconductor chip 210 and corresponding electrical connection elements associated therewith, including the backside conductive material layer 214 (FIG. 2A) which may be disposed on the back surface of the first semiconductor chip 210 and the bump layer 216 disposed on the upper surface of the first semiconductor chip 210.

An electrical connection layer 218 may be disposed on the back surface of the backside conductive material layer 214 (FIG. 2A) which may be disposed on the back surface of the first semiconductor chip 210 for facilitating connection between the first semiconductor structure 206 and the first leadframe 202, as previously described in conjunction with FIG. 2A. Likewise, an electrical connection layer 220 may be disposed on the upper surface of the bump layer 216 of the first semiconductor structure 206 for facilitating connection between the first and second semiconductor structures, as previously described in conjunction with FIG. 2A. The electrical connection layers 218, 220 may comprise, for example solder or solder paste (e.g., Sn/Pb or Sn/Ag based alloy), or a conductive epoxy, although embodiments of the present disclosure are not limited thereto.

The second semiconductor structure 208 may be stacked vertically on the first semiconductor structure 206 so that the back surface of the second semiconductor structure 208 is facing down towards the upper surface of the first semiconductor structure 206 (i.e., front-side up), as shown in FIG. 4B. Specifically, the first and second semiconductor structures 206, 208 may at least partially overlap one another in a plan view. The second semiconductor structure 208 may comprise the second semiconductor chip 212 and corresponding electrical connection elements associated therewith, which may include a backside conductive material layer 214 (FIG. 2A) disposed on the back surface of the second semiconductor chip 212.

An attachment process may then be performed to form an electrical and physical connection between the first semiconductor structure 206 and the first leadframe 202, and between the first semiconductor structure 206 and the second semiconductor structure 208. For example, when one or more of the electrical connection layers 218, 220 comprises solder or solder paste (e.g., Sn/Pb or Sn/Ag based alloy), a solder reflow process may be used for electrically and physically affixing the first semiconductor structure 206 to the first leadframe 202 and/or the first semiconductor structure 206 to the second semiconductor structure 208 through the respective electrical connection layers 218, 220. Alternatively or in addition, when one or more of the electrical connection layers 218, 220 comprises a conductive epoxy, an epoxy cure process may be used for electrically and physically bonding the first semiconductor structure 206 to the first leadframe 202 and/or the first semiconductor structure 206 to the second semiconductor structure 208 through the respective electrical connection layers 218, 220.

In FIG. 4B, each of the first and second semiconductor chips 210, 212 is oriented having its back surface facing towards the first leadframe (i.e., front-side up). It is to be appreciated, however, that in some embodiments, each of the first and second semiconductor chips 210, 212 may alternatively be oriented such that their upper surface is facing towards the first leadframe 202 (i.e., both semiconductor chips 210, 212 flipped upside down), with some modifications, such as a bump layer added to both chips 210, 212. In either scenario, the first and second semiconductor chips 210, 212 will be connected in series with each other; a backside terminal of one chip being electrically connected to a frontside terminal of the other chip. The orientation will only affect which terminals of the first and second semiconductor chips 210, 212 are connected to the first and second leadframes 202, 204.

In FIG. 4C, an electrical connection between the second semiconductor chip 212 and the second leadframe 204 is provided. In the example shown in FIG. 4C, the electrical connection may be made using a wire connection 222, such as a bond wire, as previously described in conjunction with the exemplary semiconductor device 200 shown in FIG. 2A. In one or more embodiments, the wire connection 222 may comprise a metal (e.g., copper or gold) or another low-resistance conductive material, although embodiments of the invention are not limited to any specific material for forming the wire connection 222. A conductive pad (not explicitly shown, but implied) may be provided on an upper surface of the second semiconductor chip 212 that is configured to receive a first end of the wire connection 222. A second end of the wire connection 222, opposite the first end, may be attached to an upper surface of the second leadframe 204. The respective ends of the wire connection 222 may be attached to their corresponding structures using a wire bonding process or the like, as will be known by those skilled in the art.

Alternatively, FIG. 4D depicts an illustrative embodiment in which the electrical connection between the second semiconductor chip 212 and the second leadframe 204 may be made using a conductive clip 252, as previously described in conjunction with the exemplary semiconductor device 250 shown in FIG. 2B. The exemplary process step depicted in FIG. 4D may replace the process step depicted in FIG. 4C.

With reference to the embodiment shown in FIG. 4D, an electrical connection layer 254 may be provided on the upper surface of the second semiconductor chip 212 and an electrical connection layer 256 may be provided on the upper surface of the second leadframe 204. Each of the electrical connection layers 245 and 256 may comprise solder or solder paste (e.g., Sn/Pb or Sn/Ag based alloy) or another conductive material (e.g., conductive epoxy).

As previously described in conjunction with the electrical connections layers 218 and 220, when one or more of the electrical connection layers 254, 256 comprises solder or solder paste, a solder reflow process may be used for electrically and physically affixing the second semiconductor chip 212 to a first end of the conductive clip 252 and/or for electrically and physically affixing a second end of the conductive clip 252 to the second leadframe 204 through the respective electrical connection layers 254, 256. Alternatively or in addition, when one or more of the electrical connection layers 254, 256 comprises a conductive epoxy, an epoxy cure process may be used for electrically and physically bonding the conductive clip 252 to the second semiconductor chip 212 and/or the second leadframe through the respective electrical connection layers 254, 256.

The first and second leadframes 202, 204 and the first and second semiconductor chips 210, 212, along with their respective electrical connection layers and electrical connection between the second semiconductor chip 212 and the second leadframe 204, may be encapsulated, as shown in FIG. 4E. Specifically, a molding compound 224 may be formed to surround (i.e., extend around) the first and second leadframes 202, 204, the first and second semiconductor chips 210, 212 and their respective electrical connection elements 216, 218, 220, and the wire connection 222, to form the packaged semiconductor device 200. The structure shown in FIG. 4D which employs the conductive clip 252 in place of the wire connection 222 may be encapsulated in a similar manner in fabricating the exemplary semiconductor device 250 shown in FIG. 2B. Although the first and second semiconductor chips 210, 212 in this embodiment are stacked vertically, rather than spaced laterally from one another, and therefore the semiconductor device 200 will exhibit a thicker overall cross-sectional profile (i.e., height) compared to the exemplary semiconductor device 100 shown in FIG. 1, the fabrication process may be simpler, and therefore less costly. Another potential benefit may be reduced package dimensions (e.g., in the x-axis direction and/or y-axis direction). Consequently, the semiconductor device 200 may be advantageous in certain applications wherein a low-profile device is not required.

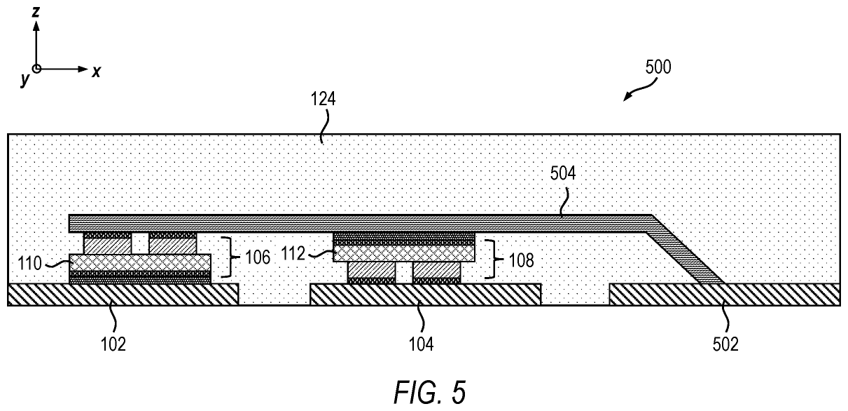

Aspects according to one or more embodiments of the present disclosure may be used to provide connection to a third leadframe. This may find beneficial application, for example, when connecting high-side and low-side MOSFET devices in series and providing external access to the switching node between the two MOSFET devices. By way of example only and without limitation, FIG. 5 is a cross-sectional view depicting at least a portion of an exemplary semiconductor device 500 which provides an external connection to an internal switching node of the first and second semiconductor chips, according to one or more embodiments of the present disclosure. The semiconductor device 500 is essentially the same as the illustrative semiconductor device 100 shown in FIG. 1, with the addition of a third leadframe for providing external to the internal switching node of the first and second semiconductor chips.

With reference to FIG. 5, the semiconductor device 500 includes the first leadframe 102 and the second leadframe 104, on which the first semiconductor structure 106 and the second semiconductor structure 108, respectively, are arranged. The first and second leadframes 102, 104 are separated laterally from one another (e.g., in an x-axis and/or y-axis direction) and are formed of a conductive material, such as a metal (e.g., copper) or metal compound, although embodiments are not limited to any specific material(s) for forming the leadframes. The semiconductor device 500 further includes a third leadframe 502 separated laterally from the first and second leadframes 102, 104 (e.g., in an x-axis and/or y-axis direction).

Although described as independent structures herein, it is to be appreciated that the first, second and third leadframes 102, 104, 502 are generally formed as distinct portions of the same leadframe. However, while the first, second and third leadframes 102, 104, 502 may be physically part of the same leadframe structure, from a practical standpoint each of the leadframes may be at different voltage potentials. It is contemplated that in some embodiments, the first, second and third leadframes 102, 104, 502 may also be physically separated from one another. The first, second and third leadframes 102, 104, 502 form external electrical connections of the semiconductor device 500.

As previously described in conjunction with FIG. 1, the first semiconductor structure 106 comprises the first semiconductor chip (i.e., die) 110 having an active device formed therein, and may also include connection structures, such as the backside conductive material layer 114, interconnect (i.e., bump) layer 116, and electrical connection layers 118, 120 (see FIG. 1). Likewise, the second semiconductor structure 108 comprises the second semiconductor chip 112 having an active device formed therein, and may also include connection structures, such as the backside conductive material layer 114, interconnect (i.e., bump) layer 116, and electrical connection layers 118, 120 (see FIG. 1).

The first semiconductor chip 110 is oriented on the first leadframe 102 such that its back surface faces the first leadframe 102 (i.e., right-side up). The second semiconductor chip 112 is oriented on the second leadframe 104, such that its upper surface faces the second leadframe 104 (i.e., upside down). In this regard, the configuration of the first and second semiconductor structures 106, 108 is consistent with the semiconductor device 100 of FIG. 1. However, the semiconductor device 500 includes a conductive clip 504 that is configured in a different manner compared to the conductive clip 122 in the semiconductor device 100 shown in FIG. 1. Specifically, the conductive clip 504 includes a first end portion connected to the first semiconductor structure 106, a middle portion connected to the second semiconductor structure 108, and a second end portion, opposite to the first end portion, connected to the third leadframe 502. In one or more embodiments, the conductive clip 504 extends laterally (in the x-axis direction), from the first semiconductor structure 106, past the second semiconductor structure 108, to some distance between the second and third leadframes 104, 502, at which point the conductive clip 504 extends downward (in a z-axis direction) to contact the third leadframe 502.

It should be appreciated that, in some embodiments, the relative locations of the first and second semiconductor chips 110, 112 and the third leadframe 502 are flexible and do not need to exactly match the illustrative arrangement of the device 500 shown in FIG. 5. For example, the third leadframe 502 may, alternatively, be arranged between the first and second leadframes 102, 104 in the x-axis direction, or the third leadframe 502 may be arranged in line (i.e., aligned) with either the first or second leadframe 102, 104 in the x-axis direction, but behind or in front of the corresponding first or second leadframe 102, 104 in the y-axis direction. Various other alternative configurations of the first, second and third leadframes 102, 104, 502 (e.g., including “offset” arrangements) are similarly contemplated, as will become apparent to those skilled in the art given the teachings herein, and such alternative embodiments are within the scope of the inventive concept.

In one or more embodiments, the semiconductor device 500 may be encapsulated by the molding compound 124, which surrounds the first semiconductor structure 106, the second semiconductor structure 108, the first, second and third leadframes 102, 104, 502, and the conductive clip 504, to thereby form a packaged semiconductor device.

In the semiconductor device 500 shown in FIG. 5, the active device formed on the first semiconductor chip 110 may comprise, for example, a first vertical transistor device (e.g., a high-side vertical MOSFET). Likewise, the active device formed on the second semiconductor chip 112 may include, for example, a second vertical transistor device (e.g., a low-side vertical MOSFET). As previously stated, a vertical MOSFET typically includes a drain terminal on a back surface of the device and gate and source terminals on an upper surface of the device.

In a power switching application, the high-side MOSFET includes a source connected to VDD, and a drain connected to a drain of the low-side MOSFET. The low-side MOSFET includes a source often connected to VSS or ground. Thus, in some embodiments, the first leadframe 102 may be connected to VDD, the second leadframe 104 may be connected to VSS or ground, and the third leadframe 502 may be provide external access to the common drain connection of the high-side and low-side MOSFETs forming the internal switching node of the circuit.

In one or more embodiments, formation of the exemplary device structures described herein may involve deposition of certain materials and layers by physical vapor deposition (PVD), chemical vapor deposition (CVD), atomic layer deposition (ALD), molecular beam epitaxy (MBE), or any of the various modifications thereof, including, for example, plasma-enhanced chemical vapor deposition (PECVD), metal-organic chemical vapor deposition (MOCVD), low pressure chemical vapor deposition (LPCVD), electron-beam physical vapor deposition (EB-PVD), and plasma-enhanced atomic layer deposition (PE-ALD). The depositions can be epitaxial processes, and the deposited material can be crystalline. In one or more embodiments, formation of a layer can be achieved using a single deposition process or multiple deposition processes, where, for example, a conformal layer is formed by a first process (e.g., ALD, PE-ALD, etc.) and a fill is formed by a second process (e.g., CVD, electrodeposition, PVD, etc.); the multiple deposition processes can be the same or different.

As used herein, the term “semiconductor” may refer broadly to an intrinsic semiconductor material that has been doped, that is, into which a doping agent has been introduced, giving it different electrical properties than the intrinsic semiconductor material, or it may refer to intrinsic semiconductor material that has not been doped. Doping may involve adding dopant atoms to an intrinsic semiconductor material, which thereby changes electron and hole carrier concentrations of the intrinsic semiconductor material at thermal equilibrium. Dominant carrier concentration in an extrinsic semiconductor material generally determines the conductivity type of the semiconductor material.

The term “metal,” as used herein, is intended to refer to any electrically conductive material, regardless of whether the material is technically defined as a metal from a chemistry perspective or not. Thus “metals” as used herein will include such materials as, for example, aluminum, copper, silver, gold, etc., and will further include materials such as, for example, graphene, germanium, gallium arsenide, highly-doped polysilicon (commonly used in most MOSFET devices), etc. This is to be distinguished from the definition of a “metal” from a physics perspective, which usually refers to those elements having a partially filled conduction band and having lower resistance toward lower temperature.

As used herein, the term “insulating” (e.g., insulating material used for the molding compound 124, 224) may generally denote a material having a room temperature conductivity of less than about 10⁻¹⁰ (Ω-m)⁻¹. Suitable insulating materials may include, but are not limited to, silicon oxide, silicon nitride, silicon oxynitride, boron nitride, high-dielectric constant (high-k) materials, or any combination of these materials. Non-limiting examples of high-k materials may include, for example, metal oxides, such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate, ceramics, etc. High-k materials may further include dopants such as lanthanum, aluminum, etc.

Spatially descriptive terms such as, for example, “below,” “above,” “upper,” “lower,” “horizontal,” “lateral,” “vertical,” “front,” “back,” and like terms as may be used herein, are intended to indicate a position of elements, structures or features relative to one another as illustrated in the figures, rather than absolute positioning. It will be understood, however, that these terms are intended to encompass different orientations of a device or structure in place of or in addition to the orientation depicted in the figures. Thus, the semiconductor device may be otherwise oriented (e.g., rotated 90 degrees or at other orientations), and the spatially relative descriptions used herein may be interpreted accordingly.

It will also be understood that when an element such as a layer, region or substrate is referred to as being “atop,” “above,” “on” or “over” another element, it is broadly intended that the element be in direct contact with the other element or intervening elements can also be present. In contrast, when an element is referred to as being “directly on” or “directly over” another element, it is intended that there are no intervening elements present. Likewise, it should be appreciated that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

At least a portion of the techniques of the present invention may be implemented in an integrated circuit. In forming integrated circuits, identical die are typically fabricated in a repeated pattern on a surface of a semiconductor wafer. Each die includes a device described herein, and may include other structures and/or circuits. The individual die are cut or diced from the wafer, then packaged as an integrated circuit. One skilled in the art would know how to dice wafers and package die to produce integrated circuits. Any of the exemplary structures illustrated in the accompanying figures, or portions thereof, may be part of an integrated circuit. Integrated circuits so manufactured are considered part of this invention.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from having enhanced edge termination structures therein (e.g., power IC devices) formed in accordance with one or more embodiments of the invention.

An integrated circuit in accordance with aspects of the present disclosure can be employed in essentially any application and/or electronic system involving enhanced breakdown voltage structures, such as, but not limited to, power metal-oxide semiconductor field-effect transistors (MOSFETs), Schottky diodes, etc. Suitable systems and applications for implementing embodiments of the invention may include, but are not limited to, AC-DC and DC-DC conversion, motor control, and power supply OR-ing (“OR-ing” is a particular type of application that parallels multiple power supplies to one common power bus in a redundant power system architecture). Systems incorporating such integrated circuits are considered part of this invention. Given the teachings of the present disclosure provided herein, one of ordinary skill in the art will be able to contemplate other implementations and applications of embodiments of the invention.

The illustrations of embodiments of the invention described herein are intended to provide a general understanding of the various embodiments, and they are not intended to serve as a complete description of all the elements and features of apparatus and systems that might make use of the structures and semiconductor fabrication methodologies described herein. Many other embodiments will become apparent to those skilled in the art given the teachings herein; other embodiments are utilized and derived therefrom, such that structural and logical substitutions and changes can be made without departing from the scope of this disclosure. The drawings are also merely representational and are not necessarily drawn to scale. Accordingly, the specification and drawings are to be regarded in an illustrative rather than a restrictive sense.

Embodiments of the invention are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises.” “comprising,” “includes” and/or “including,” when used in this specification, specify the presence of stated features, steps, operations, elements, and/or components, but do not preclude the presence or addition of one or more other features, steps, operations, elements, components, and/or groups thereof.

It will be understood that, although ordinal terms such as “first,” “second,” etc., may be used herein to describe various elements, these elements should not be limited by such terms. These terms are only used to distinguish one element from another and should not be interpreted as conveying any particular order of the elements with respect to one another. For example, a first element could be termed a second element, and, similarly, a second element could be termed a first element, without changing the principle of operation of the device or departing from the scope of the present disclosure.

As may be used herein, the term “and/or” when used in conjunction with an associated list of elements is intended to include any and all combinations of one or more of the associated listed elements. For example, the phrase “A and/or B” is intended to include element A alone, element B alone, or elements A and B.

The corresponding structures, materials, acts, and equivalents of all means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the various embodiments with various modifications as are suited to the particular use contemplated.

The abstract is provided to comply with 37 C.F.R. § 1.72 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, inventive subject matter lies in less than all features of a single embodiment. Thus, the following claims are hereby incorporated into the Detailed Description, with each claim standing on its own as separately claimed subject matter.

Given the teachings of embodiments of the invention provided herein, one of ordinary skill in the art will be able to contemplate other implementations and applications of the techniques of embodiments of the invention. Although illustrative embodiments of the invention have been described herein with reference to the accompanying drawings, it is to be understood that embodiments of the invention are not limited to those precise embodiments, and that various other changes and modifications are made therein by one skilled in the art without departing from the scope of the appended claims.

What is claimed is:

1. A semiconductor device, comprising:
a first semiconductor die including a first surface and a second surface opposite the first surface, the first semiconductor die including a first active device formed therein, the first active device comprising a first terminal on the first surface and a second terminal on the second surface;
a second semiconductor die including a third surface and a fourth surface opposite the third surface, the second semiconductor die including a second active device formed therein, the second active device comprising a third terminal on the third surface and a fourth terminal on the fourth surface;
a first interconnect layer between the first surface and the fourth surface, the first interconnect layer configured to provide vertical separation between the first and second semiconductor dies and to provide electrical connection between the first terminal and the fourth terminal; and
a conductive element having a first end electrically connected to the third surface,
wherein the second surface of the first semiconductor die is electrically connected to a first leadframe, and a second end of the conductive element is electrically connected to a second leadframe.

2. The semiconductor device according to claim 1, further comprising a first electrical connection layer between the first leadframe and the second surface the first semiconductor die, the first semiconductor die being attached to the first leadframe via the first electrical connection layer.

3. The semiconductor device according to claim 2, further comprising a second electrical connection layer between the first surface of the first semiconductor die and the fourth surface of the second semiconductor die, the first semiconductor die being attached to the second semiconductor die via the second electrical connection layer.

4. The semiconductor device according to claim 3, wherein each of the first and second electrical connection layers comprises at least one of solder, conductive epoxy, or sintered metal material.

5. The semiconductor device according to claim 1, wherein the conductive element comprises a bond wire.

6. The semiconductor device according to claim 1, wherein the conductive element comprises a conductive clip.

7. The semiconductor device according to claim 6, further comprising:
a first electrical connection layer between a first end of the conductive clip and the third surface of the second semiconductor die; and
a second electrical connection layer between a second end of the conductive clip and the second leadframe,
wherein the first end of the conductive clip is attached to the second semiconductor die via the first electrical connection layer, and the second end of the conductive clip is attached to the second leadframe via the second electrical connection layer.

8. The semiconductor device according to claim 1, further comprising:
a first conductive material layer on the second surface of the first semiconductor die; and
a second conductive material layer on the fourth surface of the second semiconductor die,
wherein the first conductive material layer comprises the second terminal of the first active device, and the second conductive material layer comprises the fourth terminal of the second active device.

9. The semiconductor device according to claim 1, wherein the first and second leadframes are configured as laterally spaced portions of a common leadframe of the semiconductor device.

10. The semiconductor device according to claim 1, further comprising:
a second interconnect layer between the second surface of the first semiconductor die and the first leadframe,
wherein the second interconnect layer is configured to provide vertical separation between the first semiconductor die and the first leadframe and to provide electrical connection between the second terminal and the first leadframe.

11. The semiconductor device according to claim 10, wherein each of the first and second interconnect layers comprises at least one of: one or more conductive standoffs, one or more patterned metal structures, and one or more solder bumps.

12. The semiconductor device according to claim 1, wherein the first surface is an upper surface of the first semiconductor die, the second surface is a bottom surface of the first semiconductor die, the third surface is an upper surface of the second semiconductor die, and the fourth surface is a bottom surface of the second semiconductor die.

13. The semiconductor device according to claim 1, wherein the first surface is a bottom surface of the first semiconductor die, the second surface is an upper surface of the first semiconductor die, the third surface is a bottom surface of the second semiconductor die, and the fourth surface is an upper surface of the second semiconductor die.

14. A semiconductor device, comprising:
a first semiconductor die including a first active device formed therein, the first semiconductor die comprising a first upper surface and a first bottom surface opposite the first upper surface, the first semiconductor die electrically connected to a first leadframe and configured such that the first bottom surface faces the first leadframe;
a second semiconductor die spaced laterally from the first semiconductor die and including a second active device formed therein, the second semiconductor die comprising a second upper surface and a second bottom surface opposite the second upper surface, the second semiconductor die electrically connected to a second leadframe and configured such that the second upper surface faces the second leadframe;
a conductive element electrically connecting the first and second semiconductor dies;
a first interconnect layer between the first upper surface and a first end of the conductive element, the first interconnect layer configured to provide vertical separation and electrical connection between the first semiconductor die and the conductive element; and
a second interconnect layer between the second upper surface and the second leadframe, the second interconnect layer configured to provide vertical separation and electrical connection between the second semiconductor die and the second leadframe.

15. The semiconductor device according to claim 14, further comprising a first electrical connection layer between the first leadframe and the first bottom surface the first semiconductor die, the first semiconductor die being attached to the first leadframe via the first electrical connection layer.

16. The semiconductor device according to claim 15, further comprising a second electrical connection layer between the second upper surface of the second semiconductor die and the second leadframe, the second semiconductor die being attached to the second leadframe via the second electrical connection layer.

17. The semiconductor device according to claim 16, wherein each of the first and second electrical connection layers comprises at least one solder, conductive epoxy, or sintered metal material.

18. The semiconductor device according to claim 16, further comprising:
a third electrical connection layer between the first interconnect layer and a first end of the conductive element; and
a fourth electrical connection layer between the second bottom surface and a second end of the conductive element laterally opposite the first end,
wherein the conductive element is attached to the first and second semiconductor dies via the third and fourth electrical connection layers, respectively.

19. The semiconductor device according to claim 14, wherein the conductive element comprises a conductive clip.

20. The semiconductor device according to claim 19, further comprising:
a first electrical connection layer between a first end of the conductive clip and the first upper surface of the first semiconductor die; and
a second electrical connection layer between a second end of the conductive clip and the second surface of the second semiconductor die,
wherein the first end of the conductive clip is attached to the first semiconductor die via the first electrical connection layer, and the second end of the conductive clip is attached to the second semiconductor die via the second electrical connection layer.

21. The semiconductor device according to claim 14, wherein the first and second semiconductor dies are identical to each other, and the conductive element electrically connects the first and second active devices in a series connection arrangement.

22. The semiconductor device according to claim 14, wherein an upper surface of the first interconnect layer and the second bottom surface of the second semiconductor die are coplanar with each other in a vertical direction.

23. The semiconductor device according to claim 14, wherein the first active device comprises a first terminal on the first upper surface and a second terminal on the first bottom surface, and the second active device comprises a third terminal on the second upper surface and a fourth terminal on the second bottom surface, the semiconductor device further comprising:
a first conductive material layer on the first bottom surface, the first conductive material layer comprising the second terminal of the first active device; and
a second conductive material layer on the second bottom surface, the second conductive material layer comprising the fourth terminal of the second active device.

24. The semiconductor device according to claim 14, further comprising a third leadframe, wherein the conductive element is electrically connected to the third leadframe.

25. A method of fabricating a semiconductor device including at least first and second series-connected semiconductor dies, the method comprising:
providing a first semiconductor die including a first surface and a second surface opposite the first surface, the first semiconductor die including a first active device formed therein, the first active device comprising a first terminal on the first surface and a second terminal on the second surface;
electrically connecting the second surface of the first semiconductor die to a first leadframe of the semiconductor device;
providing a second semiconductor die including a third surface and a fourth surface opposite the third surface, the second semiconductor die including a second active device formed therein, the second active device comprising a third terminal on the third surface and a fourth terminal on the fourth surface;
forming a first interconnect layer between the first surface of the first semiconductor die and the fourth surface of the second semiconductor die, the first interconnect layer being configured to provide vertical separation between the first and second semiconductor dies and to provide electrical connection between the first terminal of the first active device and the fourth terminal of the second active device; and
forming a conductive element having a first end electrically connected to the third surface of the second semiconductor die and having a second end electrically connected to a second leadframe of the semiconductor device.

26. A method of fabricating a semiconductor device including at least first and second series-connected semiconductor dies, the method comprising:
providing a first semiconductor die including a first active device formed therein, the first semiconductor die comprising a first upper surface and a first bottom surface opposite the first upper surface;
electrically connecting the first semiconductor die to a first leadframe of the semiconductor device, the first semiconductor die being configured such that the first bottom surface faces the first leadframe;
providing a second semiconductor die spaced laterally from the first semiconductor die and including a second active device formed therein, the second semiconductor die comprising a second upper surface and a second bottom surface opposite the second upper surface;
electrically connecting the second semiconductor die to a second leadframe of the semiconductor device, the second semiconductor die being configured such that the second upper surface faces the second leadframe;
forming a conductive element electrically connecting the first and second semiconductor dies;
forming a first interconnect layer between the first upper surface of the first semiconductor die and a first end of the conductive element, the first interconnect layer being configured to provide vertical separation and electrical connection between the first semiconductor die and the conductive element; and
forming a second interconnect layer between the second upper surface of the second semiconductor die and the second leadframe, the second interconnect layer being configured to provide vertical separation and electrical connection between the second semiconductor die and the second leadframe.
